(19) United States
(12) Patent Application Publication
(10) Pub. No.: US 2020/0402823 A1
(43) Pub. Date: Dec. 24, 2020

(54) LASER ANNEALING DEVICE, LASER ANNEALING METHOD, AND ACTIVE MATRIX SUBSTRATE PRODUCTION METHOD

(71) Applicant: SAKAI DISPLAY PRODUCTS CORPORATION, Sakai-shi, Osaka (JP)

(72) Inventors: NOBUTAKE NODERA, Sakai-shi, Osaka (JP); TOMOHIRO INOUE, Sakai-shi, Osaka (JP); SHINJI KOIWA, Sakai-shi, Osaka (JP); SATOSHI MICHINAKA, Sakai-shi, Osaka (JP)

(73) Assignee: SAKAI DISPLAY PRODUCTS CORPORATION, Sakai-shi, Osaka (JP)

(21) Appl. No.: 16/977,781

(22) PCT Filed: Mar. 7, 2018
(86) PCT No.: PCT/JP2018/008799

§ 371 Date: Sep. 2, 2020

(51) Int. Cl. H01L 21/67; H01L 21/02; H01L 27/12; B23K 26/00; B23K 26/06; B23K 26/082

(52) U.S. Cl. CPC H01L 21/67115; H01L 21/02532; H01L 21/02592; H01L 21/02678; B23K 2101/40; B23K 26/0006; B23K 26/0608; B23K 26/0648; B23K 26/082; H01L 27/1285

(57) ABSTRACT

A laser annealing apparatus 100 includes a laser irradiation device 10 to emit a plurality of laser beams LB toward an irradiation region R1 of a stage 20, the laser irradiation device including: a laser device to emit a laser beam LA; and a convergence unit that includes a microlens array 34 having a plurality of microlenses 34A arranged in m rows and n columns and a mask 32 having a plurality of apertures 32A, the convergence unit 30 receiving the laser beam from the laser device to form respective convergence points of the plurality of laser beams within the irradiation region R1. The plurality of laser beams are p rows and q columns of laser beams formed by p rows and q columns of microlenses (p<m or q<n) among the m rows and n columns of microlenses. The laser irradiation device further includes a disturbance mechanism to alter the relative positioning between the convergence unit 30 and the irradiation region R1 so that, from among the m rows and n columns of microlenses, at least two different sets of p rows and q columns of microlenses are selectable.

### TECHNICAL FIELD

The present invention relates to a laser annealing method and a laser annealing apparatus suitably used for the production of a semiconductor device that includes thin film transistors, and a method of producing an active matrix substrate, for example.

### BACKGROUND ART

Thin film transistors (hereinafter, “TFT”) are used as switching elements on an active matrix substrate, for example. In the present specification, such TFTs will be referred to as “pixel TFTs”. As pixel TFTs, amorphous silicon TFTs whose active layer is an amorphous silicon film (hereinafter abbreviated as an “a-Si film”), and crystalline silicon TFTs whose active layer is a crystalline silicon film (hereinafter abbreviated as a “c-Si film”) such as a polycrystalline silicon film, have been widely used. Generally speaking, a c-Si film has a higher field-effect mobility than that of an a-Si film, and therefore a crystalline silicon TFT has a higher current driving power (i.e., a larger ON current) than that of an amorphous silicon TFT.

In an active matrix substrate for use in a display apparatus or the like, the active layers of crystalline silicon TFTs may be formed by, after creating an a-Si film on a glass substrate, irradiating the a-Si film with a laser beam so as to crystallize it, for example.

As a crystallization method based on laser annealing, a method has been proposed which employs a microlens array to exclusively irradiate with a laser beam a plurality of regions of an a-Si film to become active layers of TFTs, thus to partially crystallize the a-Si film in order to form c-Si regions (which may be referred to as “crystalline silicon islands” or “c-Si islands”) (Patent Documents 1, 2 and 3). In the present specification, this crystallization method will be referred to as a “partial laser annealing technique”. By using a partial laser annealing technique, as compared to any conventional laser annealing technique that scans the entire surface of an a-Si film with linear-shaped laser light (which may be referred to as an excimer laser annealing technique: ELA technique), the time required for crystallization can be considerably reduced, whereby mass producibility can be enhanced. The entire disclosure of Patent Documents 1 to 3 will be incorporated herein by reference.

### CITATION LIST

### Patent Literature

[Patent Document 1] Japanese Laid-Open Patent Publication No. 2011-29411
[Patent Document 2] International Publication No. 2011/132559
[Patent Document 3] International Publication No. 2017/145519

### SUMMARY OF INVENTION

### Technical Problem

However, a displayed image (e.g., a gray scale image all across the screen) on a liquid crystal display apparatus that is formed by using the conventional partial laser annealing method described in Patent Documents 1 to 3 may experience a number of lines of unevenness (hereinafter referred to as “streak unevenness”). A presumable reason for this is that, within the substrate plane, variations have occurred in the crystallinity of the c-Si islands along the scanning direction of a laser beam during partial laser annealing. Details thereof will be described later.

When variations in crystallinity occur among the c-Si islands within the substrate plane, the TFT characteristics will also vary within the substrate plane, thus possibly lowering reliability.

The present invention has been made in view of the above circumstances, and an objective thereof is to provide a laser annealing apparatus and laser annealing method that can reduce variations in crystallinity within the substrate plane.

### Solution to Problem

A laser annealing apparatus according to one embodiment of the present invention comprises: a stage having a bed plane for receiving a substrate; and a laser irradiation device to emit a plurality of laser beams toward the bed plane to form an irradiation region on the bed plane, the laser irradiation device including: a laser device to emit a laser beam; and a convergence unit that includes a microlens array having a plurality of microlenses arranged in m rows and n columns and a mask having a plurality of apertures disposed respectively for the plurality of microlenses, wherein the convergence unit receives the laser beam emitted from the laser device to form respective convergence points of the plurality of laser beams within the irradiation region, wherein, the plurality of laser beams are p rows and q columns of laser beams formed by p rows and q columns of microlenses (p<m or q<n) among the plurality of microlenses arranged in the m rows and the n columns; and the laser irradiation device further includes a disturbance mechanism to alter a relative positioning between the convergence unit and the irradiation region so that, from among the plurality of microlenses arranged in the m rows and the n columns, at least two different sets of p rows and q columns of microlenses are selectable.

In one embodiment, the laser beam is large enough to irradiate more microlenses than p rows and q columns of microlenses among the plurality of microlenses arranged in the m rows and the n columns; the laser irradiation device further includes a light shield plate having a light-transmitting portion that stipulates the irradiation region; and the light-transmitting portion has an area corresponding to p rows and q columns of microlenses (p<m or q<n) among the plurality of microlenses arranged in the m rows and the n columns. The light shield plate may be disposed between the laser device and the convergence unit, or disposed between the convergence unit and the substrate.

In one embodiment, the disturbance mechanism causes a position of the convergence unit with respect to the irradiation region to move along a disturbance direction which is orthogonal to a scanning direction of the laser irradiation device.

In one embodiment, the disturbance mechanism causes a position of the convergence unit with respect to the irradiation region to move along a scanning direction of the laser irradiation device.

A laser annealing method according to one embodiment of the present invention is a method of sequentially converging a plurality of laser beams in a plurality of regions of an amorphous silicon film to form a plurality of crystalline silicon islands arranged in M rows and N columns, the method comprising: step A: a step of providing: a stage having a bed plane for receiving a substrate; and a laser irradiation device to emit a plurality of laser beams toward the bed plane to form an irradiation region on the bed plane, the laser irradiation device including a laser device to emit a laser beam and a convergence unit that includes a microlens array having a plurality of microlenses arranged in m rows and n columns and a mask having a plurality of apertures disposed respectively for the plurality of microlenses; step B1: a step of placing on the bed plane a substrate having an amorphous silicon film on a surface thereof; step C: a step of employing the laser irradiation device to form, as the plurality of laser beams, p rows and q columns or t rows and q columns of laser beams by using p rows and q columns (p≤m and q≤n) or t rows and q columns (t<p) of microlenses among the plurality of microlenses arranged in the m rows and the n columns, and to form respective convergence points of the plurality of laser beams in the plurality of regions of the amorphous silicon film; and step C2: a step of, after step C1, causing the substrate to make a relative movement with respect to the irradiation region by one pitch along a column direction, wherein, the method comprises step D including a sequence of performing step C1 followed by step C2, and thereafter step C1, wherein step D forms a respectively corresponding convergence point p times in each of the plurality of regions to become the plurality of crystalline silicon islands arranged in M rows and N columns, and the method performs, before having formed convergence points of the plurality of laser beams in all regions of the M rows and the q columns, at least one instance of step C3: a step of, after step C1, causing a set of p microlenses to be used in forming p instances of convergence points in one of M regions belonging in one column of the plurality of regions to differ, by at least one microlens, from a set of p microlenses having been used in forming p instances of convergence points in another of the M regions.

In one embodiment, step C1 is a step of forming, as the plurality of laser beams, p rows and q columns of laser beams by using p rows and q columns of microlenses (p≤m and q<n) among the plurality of microlenses arranged in the m rows and the n columns, and forming respective convergence points of the p rows and q columns of laser beams in the plurality of regions of the amorphous silicon film; and step C3 comprises, after step C1, a step of causing the convergence unit to make a relative movement with respect to the irradiation region by at least one pitch along a row direction.

In one embodiment, step C1 is a step of forming, as the plurality of laser beams, p rows and q columns of laser beams by using p rows and q columns of microlenses (p<m and q≤n) among the plurality of microlenses arranged in the m rows and the n columns, and forming respective convergence points of the p rows and q columns of laser beams in the plurality of regions of the amorphous silicon film; and step C3 comprises, after step C1, a step of causing the convergence unit to make a relative movement with respect to the irradiation region by at least one pitch along the column direction.

One embodiment further comprises, before step C1, step B2: a step of selecting, as a selected lens set, t rows and q columns of microlenses among the plurality of microlenses arranged in the m rows and the n columns, and positioning the selected lens set so as to correspond to the irradiation region, wherein, step C1 is a step of forming the plurality of laser beams by using the selected lens set, and forming respective convergence points of the plurality of laser beams in the plurality of regions of the amorphous silicon film; step C3 is a step of, after step C1, keeping unchanged a relative positional relationship between the substrate and the irradiation region; and step D includes a sequence of performing step C2 or step C3, and thereafter step C1.

The laser annealing method may further comprise step C4: a step of, after step C1, switching the selected lens set to p rows and q columns of microlenses (t<p≤m and q≤n) among the plurality of microlenses arranged in the m rows and the n columns, and accordingly, altering an area of the irradiation region so as to correspond to the switched selected lens set and positioning the switched selected lens set so as to correspond to the altered irradiation region, wherein, before having formed convergence points of the plurality of laser beams in all regions of the M rows and the q columns, one or more instances of step C4 may be performed.

At least one instance of step C3 may be performed while 5×p instances of step C1 are performed. Alternatively, at least one instance of step C3 may be performed while p instances of step C1 are performed. The at least one instance may be randomly selected.

A method of producing an active matrix substrate according to one embodiment of the present invention comprises: a step of forming a plurality of crystalline silicon islands by any of the above laser annealing methods; and a step of forming a plurality of TFTs by using the plurality of crystalline silicon islands.

### Advantageous Effects of Invention

According to an embodiment of the present invention, there is provided a laser annealing apparatus and laser annealing method which can reduce variations in crystallinity within the substrate plane.

### BRIEF DESCRIPTION OF DRAWINGS

FIG. 1 A schematic diagram of a laser annealing apparatus according to a first embodiment.

FIG. 2 A cross-sectional view of a laser irradiation device in the laser annealing apparatus according to the first embodiment.

FIG. 3 A schematic plan view for describing a positional relationship between microlenses of a convergence unit and an irradiation region, according to the first embodiment.

FIG. 4 (a) through (g) are plan views each describing a lens set that is selectable from within the microlens array shown in FIG. 3.

FIG. 5 (a) is a schematic plan view illustrating an exemplary convergence unit to be used in a laser annealing method according to the first embodiment; and (b) is a schematic diagram illustrating exemplary converged regions of an amorphous silicon film.

FIG. 6 A diagram for describing an example of the laser annealing method according to the first embodiment.

FIG. 7 A schematic plan view for describing a positional relationship between microlenses of a convergence unit and an irradiation region, according to a second embodiment.

FIG. 8 A schematic plan view illustrating an exemplary convergence unit to be used in a laser annealing method according to the second embodiment.

FIG. 9 A diagram for describing an example of the laser annealing method according to the second embodiment.

FIG. 10 A diagram for describing an example of the laser annealing method according to a third embodiment.

FIG. 11 A cross-sectional view showing Variant 1 of the laser annealing apparatus.

FIG. 12 A perspective view for describing Variant 2 of the laser annealing apparatus.

FIG. 13 (a) through (d) are schematic diagrams describing examples for the control section in the laser annealing apparatus according to the first embodiment.

FIG. 14 (a) and (b) are schematic diagrams describing examples for the control section in the laser annealing apparatus according to the second embodiment.

FIG. 15 (a) and (b) are schematic diagrams describing examples for the control section in the laser annealing apparatus according to the third embodiment.

FIG. 16 (a) is a schematic perspective view for describing a conventional partial laser annealing method; and (b) is a schematic plan view for describing “streak unevenness” occurring in a semiconductor film that is crystallized by a conventional partial laser annealing method.

### DESCRIPTION OF EMBODIMENTS

As described above, when a plurality of c-Si islands are formed on an a-Si film by using the conventional partial laser annealing method, variations in crystallinity may occur among the c-Si islands, which may be visually recognized as lines of unevenness (streak unevenness). According to a study of the inventors, a main factor in variations in crystallinity, to which streak unevenness is ascribable, is the manufacturing variations for a microlens array of a laser annealing apparatus. As used herein, “manufacturing variations for a microlens array” are inclusive, in the context of producing a microlens array in which a plurality of lenses are arranged in a two-dimensional array, of variations in the size and shape of the plurality of lenses due to machining errors. However, rather than machining errors for each individual microlens, it is an error in a cumulative value of the machining errors associated with one row of (e.g., twenty) microlenses that causes errors in the cumulative value of irradiation doses. This makes it difficult to adopt an approach of identifying a microlens(es) that has a large machining error and abstaining from using that microlens(es). Of course, there will be lenses which significantly contribute, as well as lenses which poorly contribute, to the cumulative value of machining errors of the lens row; and there will even be lenses which contribute to a decrease in the cumulative value.

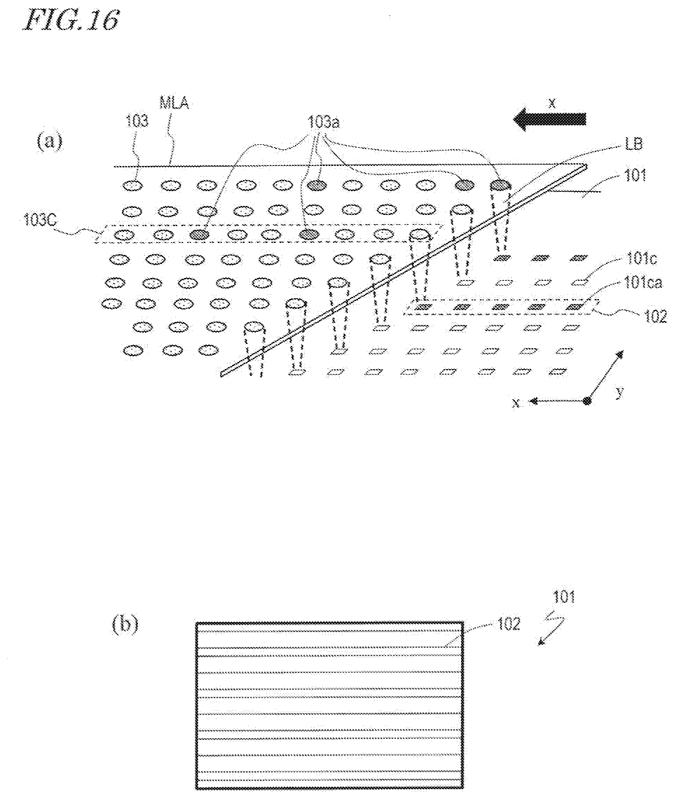

FIG. 16(a) is a schematic perspective view illustrating an example of a conventional partial laser annealing method.

In the conventional laser annealing method, an Si film 101 placed on a substrate is subjected to laser irradiation, with a laser irradiation device including a microlens array MLA that is allowed to make relative movements in the x direction (scanning direction) shown in the figure.

Herein, a plurality of selected regions (referred to as “converged regions”) of the amorphous silicon film 101 are irradiated with multiple instances of laser beams LB via the microlens array MLA, whereby c-Si islands 101c are formed in the respective converged regions of the amorphous silicon film 101. In this example, the respective converged regions are arranged along the x direction and along the y direction (which is orthogonal to the x direction), correspondingly to the regions to become active layers of TFTs.

The microlens array MLA includes a plurality of lenses 103 which are arranged in a two-dimensional array along the x direction and along the y direction. Given a column direction being defined as the x direction and a row direction being defined as the y direction, the microlens array MLA includes a plurality of lens columns, each including a plurality of lenses 103 flanking one another along the x direction. In this example, among the plurality of lens columns, some lens columns 103C include one or more lenses 103a with a large machining error(s), thus resulting in a greater cumulative value of machining errors than that of any other lens column.

As a laser beam 105 is sequentially converged through each lens 103 included in one lens column, each converged region to become the active layer of a TFT receives multiple instances of laser irradiation. If the lens column includes twenty lenses 103, then 20 instances of irradiation (shots) will be effected, whereby a c-Si island 101c is formed in this region. In other words, a plurality of c-Si islands 101c belonging in the same column will be formed by using the lenses 103 belonging in the same lens column. Those converged regions which are subjected to laser irradiation by a lens column 103C with large machining errors will experience a larger (or smaller) irradiation dose (i.e., a cumulative value over 20 instances) than does any other converged region, whereby c-Si islands 101ca with higher (or lower) crystallinity than that of any other c-Si island 101c are formed. This results in linear regions 102 having higher (or lower) crystallinity in line shapes, which may be visually recognized as streak unevenness as shown in FIG. 16(b). This problem will become more outstanding with increasingly higher definitions.

Based on the above findings, the inventors have realized that, by breaking the regularity by which the c-Si islands 101c in the same column are always crystallized by lenses 103 in the same lens column 103C, streak unevenness due to manufacturing variations associated with the microlens array MLA can be reduced.

Hereinafter, an outline of a laser annealing apparatus according to an embodiment of the present invention will be described.

A laser annealing apparatus includes: a laser irradiation device; and a stage having a bed plane for receiving a substrate having an amorphous silicon film formed thereon.

The laser irradiation device emits a plurality of laser beams in e.g. the ultraviolet region, toward a partial region (hereinafter referred to as an “irradiation region”) of the bed plane of the stage. The plurality of laser beams are converged by a plurality of microlenses, so as to form a plurality of convergence regions within the irradiation region.

Herein, the irradiation region and the convergence regions are regions stipulated by the laser irradiation device, and are defined as regions on the bed plane of the stage. In other words, the irradiation region and the convergence regions are defined irrespective of the position of the amorphous silicon film (substrate) disposed on the bed plane of the stage.

The laser irradiation device includes: a laser device to emit a laser beam; and a convergence unit to receive a laser beam emitted from the laser device and form a plurality of laser beams. The convergence unit includes: a microlens array having a plurality of microlenses; and a mask having a plurality of apertures disposed respectively for the plurality of microlenses. The laser irradiation device may further include a light shield plate having a light-transmitting portion.

The irradiation region may be stipulated by a laser device or a light shield plate, for example. The plurality of convergence regions to be created by the convergence unit are formed within the irradiation region.

On the other hand, within the amorphous silicon film (substrate), regions corresponding to the irradiation region (and the convergence regions) are referred to as the irradiated region (converged regions). Conventionally, while causing the irradiated region of the amorphous silicon film to make relative movements (e.g. by 1 pitch each along the column direction) with respect to the irradiation region, multiple instances of laser irradiation would be performed through a plurality of microlenses, whereby the amorphous silicon in the converged regions would become crystallized. Each converged region (i.e., a region to eventually become a c-Si island) might be subjected to 8 instances of laser irradiation through 8 different microlenses, for example, whereby a plurality of (e.g. M) c-Si islands belonging to one column would all be subjected to 8 instances of laser irradiation through the same 8 microlenses.

A laser annealing apparatus according to an embodiment of the present invention includes a disturbance mechanism.

In the following description, in the process of forming a plurality of (e.g. M) c-Si islands belonging to one column, a “disturbance” will refer to causing a set of 8 microlenses used in the 8 instances of laser irradiation for forming at least one c-Si island to differ, by at least one, from a set of 8 microlenses for forming another c-Si island; and any constitution which the laser irradiation device may possess for this purpose will be referred to as a “disturbance mechanism”.

The disturbance mechanism may include a mechanism which, in the process of forming a plurality of (e.g. M) c-Si islands belonging to one column, moves the set of microlenses along the row direction (which is orthogonal to the column direction) at least once, in the course of 8 instances of laser irradiation for forming at least one c-Si island (i.e., in the course of performing 8 instances of laser irradiation while causing the irradiated region of the amorphous silicon film to make relative movements by 1 pitch each along the column direction), for example.

Alternatively, the disturbance mechanism may include a mechanism which, in the process of forming a plurality of (e.g. M) c-Si islands belonging to one column, alters the positioning of the set in the convergence unit with respect to the laser beams emitted from the laser device so as to change the set of microlenses to form a plurality of convergence regions within the irradiation region at least once, in the course of 8 instances of laser irradiation for forming at least one c-Si island (i.e., in the course of performing 8 instances of laser irradiation while causing the irradiated region of the amorphous silicon film to make relative movements by 1 pitch each along the column direction), for example. For example, it may include a mechanism which moves the set of microlenses along e.g. the column direction. Alternatively, it may include a mechanism which does not move the set of microlenses along the column direction, for example. Alternatively, it may include a mechanism which alters the relative positioning between the light-transmitting portion of the light shield plate and the convergence unit (microlens array).

The disturbance mechanism may be implemented by controlling the relative positioning between the stage (or the substrate) and the convergence unit in a conventional laser irradiation device. Alternatively, the disturbance mechanism may be implemented by controlling the relative positioning between the laser device and the convergence unit.

### First Embodiment

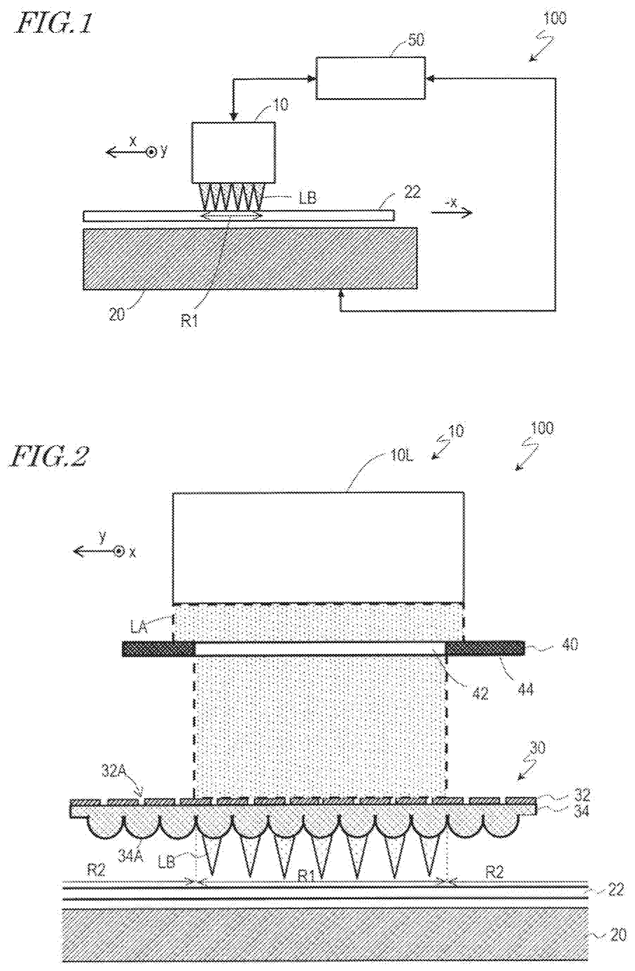

FIG. 1 is a schematic cross-sectional view of a laser annealing apparatus 100 according to a first embodiment of the present invention. FIG. 2 is a schematic cross-sectional view of a laser irradiation device 10 of the laser annealing apparatus 100.

The laser annealing apparatus 100 includes a laser irradiation device 10, a stage 20, and a control section 50 which controls them.

The stage 20 has a bed plane for receiving a substrate 22 having an amorphous silicon film formed thereon. The substrate 22 does not need to be in contact with the bed plane of the stage 20, but may be placed on the bed plane in a non-contacting state by the principles of aerostatic bearing, for example.

Toward a partial region (irradiation region) R1 of the bed plane of the stage 20, the laser irradiation device 10 emits a plurality of laser beams LB in the ultraviolet region, for example. The plurality of laser beams LB are converged by a plurality of microlenses so as to form a plurality of convergence regions within the irradiation region R1.

As shown in FIG. 2, the laser irradiation device 10 includes a laser device (laser light source) 10L which emits a laser beam LA, and a convergence unit 30 which is disposed between the laser device 10L and the stage 20 (i.e., the substrate 22 on the stage 20).

As the laser device 10L, for example, an ultraviolet laser such as a XeCl excimer laser (wavelength 308 nm) may be used. Alternatively, a solid laser element such as a YAG laser element (second harmonic: wavelength 532 nm) may be used.

Upon receiving the laser beam LA emitted from the laser device 10L, the convergence unit 30 forms the plurality of laser beams LB, and also forms respective convergence points of the plurality of laser beams LB within the irradiation region R1.

Specifically, the convergence unit 30 includes: a microlens array 34 including a plurality of microlenses (which are not limited to lenses which are smaller than 1 mm) 34A arranged in a two-dimensional array; and a mask 32 disposed between the laser device 10L and the plurality of microlenses 34A. The mask 32 has a plurality of apertures 32A disposed respectively for the plurality of microlenses 34A. Each aperture 32A is disposed correspondingly to one of the microlenses 34A. Each microlens 34A creates a convergence point of a laser beam LB having passed through the corresponding aperture 32A onto a corresponding converged region on the amorphous silicon film that is formed on the substrate 22.

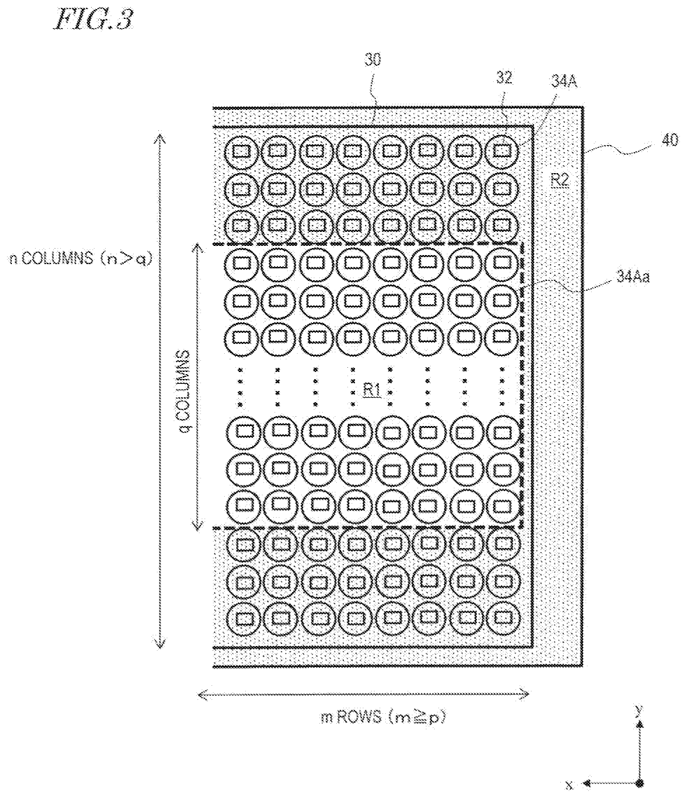

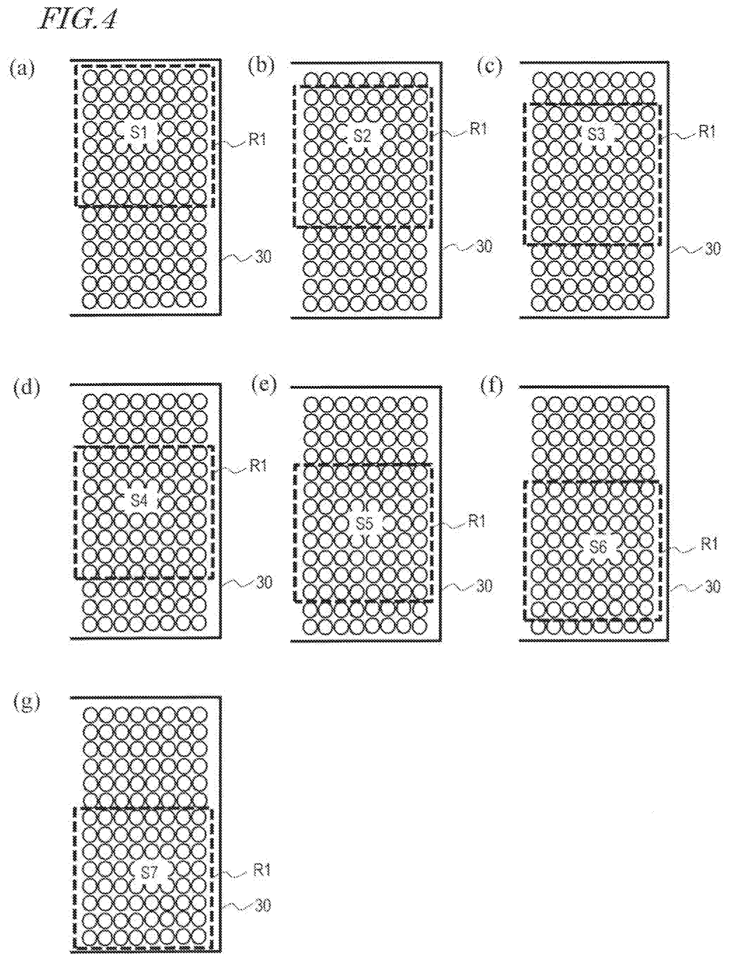

FIG. 3 is a schematic plan view for describing a positional relationship between the microlenses 34A of the convergence unit 30 and the irradiation region R1. As shown in FIG. 3, when viewed from the normal direction of the substrate 22, the plurality of microlenses 34A are arranged in a matrix along an x direction (scanning direction) and along a y direction which intersects the x direction. The x direction and the y direction may be orthogonal. Given that the x direction is the column direction, the microlenses 34A are arranged in m rows and n columns (where m and n are integers which are 2 or greater). Among the m rows and n columns of microlenses 34A in the convergence unit 30, p rows and q columns (p≤m, q<n) of microlenses 34A are located so as to overlap the irradiation region R1. The other microlenses 34A are located so as to overlap a region other than the irradiation region R1 (hereinafter referred to as the “non-irradiation region”) R2. Although not particularly limited, p and q may be such that 10≤p≤20, 100≤q≤200, for example.

The laser annealing apparatus 100 further includes a disturbance mechanism. The disturbance mechanism is able to alter the relative positioning between the convergence unit 30 and the irradiation region R1 so that, from among the plurality of microlenses 34A of the convergence unit 30 which are arranged in m rows and n columns, at least two different lens sets of p rows and q columns of microlenses 34A are selectable.

In the present embodiment, the disturbance mechanism is configured to, between shots (i.e., after performing a previous laser irradiation and before performing a next laser irradiation), cause relative movements between the convergence unit 30 and the irradiation region R1 along the y axis (in the y direction or in the −y direction). For example, by causing a relative movement between the convergence unit 30 and the irradiation region R1 by one column of microlenses 34A (one pitch) along the y axis, the lens set of microlenses 34A located within the irradiation region R1 can be shifted by one column.

The disturbance mechanism may be configured to be capable of moving the convergence unit 30 with respect to the irradiation region R1 along the y axis, or configured to be capable of moving the substrate 22 (the stage 20) and the irradiation region R1 with respect to the convergence unit 30 along the y axis.

The laser device 10L may emit a large laser beam LA that can irradiate more microlenses 34A than p rows and q columns of microlenses 34A. In this case, the laser irradiation device 10 further includes an optical element that, by restricting the range in which the laser beam LA is emitted from the laser device 10L, stipulates the irradiation region R1 within the bed plane. Such an optical element may be disposed between the laser device 10L and the stage 20 (i.e., the substrate 22 on the stage 20).

In this example, as the aforementioned optical element, the laser device 10L further includes a light shield plate 40 that is disposed between the laser device 10L and the convergence unit 30. As will be described later, the light shield plate 40 may be disposed between the convergence unit 30 and the substrate 22. The light shield plate 40 includes a light-transmitting portion 42, which stipulates the irradiation region R1, and a light-shielding portion 44 located around the light-transmitting portion 42. The light-transmitting portion 42 has an area corresponding to, among the plurality of microlenses arranged in m rows and n columns, p rows and q columns of microlenses (p m, q<n). The convergence unit 30 is disposed so that, when viewed from the normal direction of the substrate 22, only a part of the microlenses 34A of the convergence unit 30 (i.e., p rows and q columns of microlenses 34A) overlaps the light-transmitting portion 42. In the bed plane of the stage 20, the region in which the laser beams LB having passed through the light-transmitting portion 42 are able to enter defines the irradiation region R1. On the other hand, the non-irradiation region R2 includes a region which is blocked by the light-shielding portion 44 of the light shield plate 40 and which is not reached by the laser beams LB.

The laser annealing apparatus 100 also includes a scanning mechanism which causes relative movements between the irradiation region R1 created by the laser irradiation device 10 and the substrate 22 on the stage 20 along the x direction. The scanning mechanism may move the irradiation region R1 in the x direction. Alternatively, it may move the substrate 22 in the −x direction. In that case, the substrate 22 may be moved by way of moving the stage 20. Note that it is not necessary for the stage 20 itself to move; the substrate 22 may be caused to move in a non-contacting state, by the principles of aerostatic bearing.

The laser annealing apparatus 100 includes the control section 50, which controls the positional relationship between the stage 20, the substrate 22, the convergence unit 30, and the laser device 10L. This allows the aforementioned disturbance mechanism and scanning mechanism to operate. FIGS. 13(a) through (d) are schematic diagrams describing examples of operation of the control section 50.

The control section 50, as shown in e.g. FIG. 13(a), controls the stage 20 (substrate 22) so as to move along the x axis and along the y axis. This realizes the scanning mechanism, whereby c-Si islands can be formed across the entire region of the amorphous silicon film on the substrate 22. Moreover, the convergence unit 30 is controlled so as to move with respect to the laser device 10L along the y axis at least once while the stage 20 (substrate 22) is being moved along the x axis. This realizes the disturbance mechanism.

Alternatively, as shown in FIG. 13(b) and FIG. 13(c), for example, the control section 50 may implement the disturbance mechanism by controlling the laser device 10L or the light shield plate 40 to move with respect to the convergence unit 30 along the y axis at least once while the stage 20 (substrate 22) is being moved along the x axis. Furthermore, as shown in FIG. 13(d), for example, the control section 50 may implement the scanning mechanism by, while fixing the stage 20 (substrate 22), controlling the laser irradiation device 10 to move along the x axis and along the y axis.

In the laser annealing apparatus 100 of the present embodiment, while the aforementioned scanning mechanism causes the irradiation region R1 to make relative movements with respect to the substrate 22 along the x direction (stepping), laser beams LB irradiate a plurality of regions (converged regions) of the amorphous silicon film on the substrate 22 that correspond to the selected p rows and q columns of microlenses 34A. As a result of this, in each converged region, convergence points of the laser beams LB are sequentially formed by a plurality of (e.g. p herein) different microlenses 34A. In the present specification, the operation where convergence points of the laser beams LB are formed in the converged regions by using the microlenses 34A is referred to as a “laser irradiation (or shot)”. Each converged region is subjected to p instances of laser irradiation, whereby a c-Si island in island shape (crystalline silicon island) is formed.

In the conventional partial laser annealing method described above with reference to FIGS. 16(a) and (b), given the number of laser irradiations (number of shots) p for one converged region, each of the converged regions in the same column on the amorphous silicon film receives p instances of laser irradiation by using p microlenses in the same column of the microlens array. As a result, due to manufacturing variations associated with the microlens array, c-Si islands of higher (or lower) crystallinity may be formed along the column direction, thus causing streak unevenness running along the column direction.

On the other hand, according to the present embodiment, the laser annealing apparatus 100 includes the disturbance mechanism. Therefore, in the course of performing multiple instances of laser irradiation, it is possible to alter the relative positioning between the convergence unit 30 and the irradiation region R1 with an arbitrary timing, among the m rows and n columns of microlenses 34A of the convergence unit 30, whereby the lens set of p rows and q columns (referred to as the “selected lens set”) that is positioned so as to correspond to the irradiation region R1 can be shifted as desired. By causing a part or a whole of the p microlenses 34A in the selected lens set to differ, a part of the converged regions located in the same column can be subjected to p instances of laser irradiation by using different p microlenses 34A than those for another part of the converged regions. This allows the c-Si islands formed in the converged regions in the same column to differ from one another in terms of crystallinity. Therefore, even with an microlens array 34 having manufacturing variations, it is possible to restrain c-Si islands of higher (or lower) crystallinity from being placed in streaks over the entire substrate, whereby streak unevenness can be reduced.

As shown in FIG. 3, in the present embodiment, the number n of columns of microlenses 34A is made larger than the number q of columns in the selected lens set (n>q). Among the n columns of microlenses 34A, the number of columns that are not included in the selected lens set (i.e., the number of excess columns) is designated as C (C=n−q). Given that m=p, n>q, the number S of lens sets consisting of p rows and q columns of microlenses 34A that are selectable from among the m rows and n columns of microlenses 34A is (C+1). The number C of excess columns may be one or more. So long as the number C of excess columns is one or more, it becomes possible to select from among two or more lens sets, thus providing the effect of reducing streak unevenness through disturbance operations. In the example shown in FIG. 3, the number C of excess columns is six, and, as shown in FIGS. 4(a) through (g), seven lens sets S1 to S7 are selectable.

The number C of excess columns and the number p of shots for forming one c-Si island preferably satisfy formula (1) below.

2^{C+1}≥p (1)

For example, given that the number p of shots for forming a c-Si island is 20 (p=20), the number C of excess columns of microlenses 34A is preferably four or more. By ensuring that the number of combinations (subsets) (2^{C+1}) of selectable lens sets is equal to or greater than the number p of shots, for example, the lens set combinations that are used in the laser irradiations for respective ones of p adjacent converged regions adjoining along the column direction can be made mutually different. This allows formation of c-Si islands differing in crystallinity along the column direction to be suppressed more effectively.

More preferably, the number C of excess columns and the number p of shots satisfy formula (2) below.

C≥p−1 (2)

In this case, the number S of selectable lens sets is p or more. This makes it possible to perform all p instances of laser irradiation for one converged region with different columns of microlenses 34A, for example, thereby more effectively suppressing streak unevenness. For example, in an example to be described later with reference to FIG. 6, among the eight lenses to be used in the laser irradiations for two adjacent converged regions adjoining along the column direction (converged regions in the 1^{st} row and the 2^{nd} row of column k), there are seven common ones (lenses a1 to a7). On the other hand, when the microlens array 34 satisfies formula (2) above, all p lenses used in the laser irradiations for two adjacent converged regions adjoining along the column direction can be made different.

On the other hand, the number C of excess columns may be less than 2×p, for example. This is advantageous because the aforementioned effects can be obtained without considerably increasing the number of microlenses (e.g., the number of microlenses: less than p×q×2).

Note that similar effects to those associated with the use of the disturbance mechanism may also be obtained by producing a plurality of microlenses array, and randomly selecting microlens arrays to be used therefrom. However, this will result in a disadvantage of increased production cost for the microlens array.

<Laser Annealing Method>

Next, a method of performing laser annealing of an amorphous silicon film by using the laser annealing apparatus 100 will be described. Herein, a plurality of laser beams are sequentially converged onto a plurality of converged regions arranged in M rows and N columns on the amorphous silicon film, thereby forming a plurality of c-Si islands. The plurality of converged regions respectively correspond to regions in which active layers of TFTs are to be formed, for example.

First, the substrate 22 having an amorphous silicon film on its surface is placed on the bed plane of the stage of the laser annealing apparatus 100. As the substrate 22, for example, a substrate having a dielectric surface can be used, e.g., a glass substrate, a silicon substrate, or a plastic substrate (resin substrate) having heat resistance. The amorphous silicon film is to be formed on the surface of the substrate 22 by a known method such as the CVD technique. As an example, by using a hydrogen gas (H₂) and a silane gas (SiH₄), an amorphous silicon film having a thickness of e.g. 50 nm is formed.

Note that, after forming the amorphous silicon film and before subjecting the amorphous silicon film to partial laser annealing, an insulative protection film may be provided so as to cover the amorphous silicon film. Moreover, the amorphous silicon film may be subjected to a dehydrogenation annealing treatment (e.g. 450° C., 60 minutes). In the case where an insulative protection film is provided, laser beams LB may be radiated from above the insulative protection film in the partial laser annealing step.

Next, among the plurality of microlenses 34A arranged in m rows and n columns, p rows and q columns of microlenses (p≤m and q<n) 34A are used to form p rows and q columns of laser beams LB, and to form respective convergence points of the p rows and q columns of laser beams LB in a plurality of converged regions located in the irradiation region R1. This step is referred to as a “laser irradiation step”.

Then, a stepping step of causing the substrate 22 to make a relative movement with respect to the irradiation region R1 by one pitch along the scanning direction (the x direction) is performed. Thereafter, a next laser irradiation step and stepping step are performed. Thus, by repeating laser irradiation steps and stepping steps, among the M rows and N columns, a respectively corresponding convergence point is formed p times in each of the plurality of converged regions arranged in M rows and q columns (q≤N). As a result, in each of the plurality of converged regions, through p instances of laser irradiation, the region of the amorphous silicon film onto which laser beams have been converged is heated to melt and solidify, whereby an island-shaped crystalline region (c-Si island) is formed. Any region other than the converged regions remains amorphous (a-Si).

In the present embodiment, before having formed convergence points of p instances of laser beams in all regions of the M rows and the q columns, the disturbance mechanism is employed to perform, at least once, a step of causing the convergence unit 30 to make a relative movement with respect to the irradiation region R1 by at least one pitch along the y axis (in the y direction or in the −y direction). In the present specification, a step of causing the convergence unit 30 to make a relative movement with respect to the irradiation region R1 along the y axis will be referred to as a “row-direction disturbance step”. This allows at least a part of the selected lens set to be used in the laser irradiation step to differ between before the row-direction disturbance step and after the row-direction disturbance step. The timing with which to perform the row-direction disturbance step, the number of times of performing it, the number of pitches by which movements are to be made, etc., may be selected as appropriate. These may be randomly selected, too.

Thereafter, among the M rows and N columns, any other converged region of M rows and q columns is also subjected to p instances of laser irradiation by a similar method. In this manner, c-Si islands are respectively formed in the M rows and N columns of converged regions of the amorphous silicon film.

Thereafter, the amorphous silicon film having the M rows and N columns of c-Si islands formed thereon is patterned, whereby semiconductor layers to become the active layers of the TFTs are obtained. Each semiconductor layer includes a part or a whole of the corresponding c-Si island. By using these semiconductor layers, a plurality of TFTs are formed on the substrate by a known method. The substrate on which the TFTs have been formed may be suitably used as an active matrix substrate of a display apparatus such as a liquid crystal display apparatus or an organic EL display apparatus, for example.

With reference to the drawings, an example of the above laser annealing method will be described.

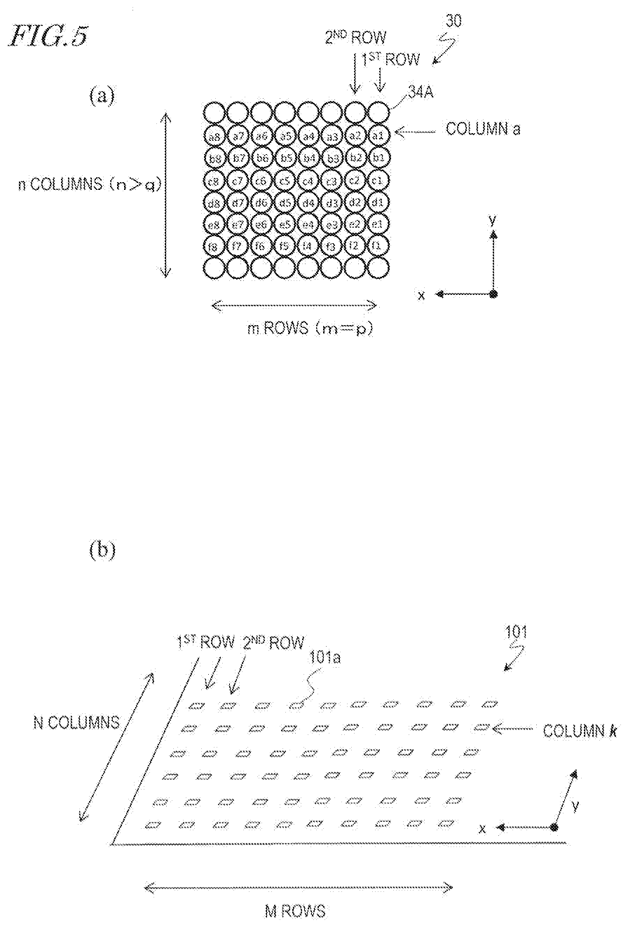

FIG. 5(a) is a schematic plan view illustrating an exemplary convergence unit 30 to be used in the laser annealing method. The convergence unit 30 includes m rows and n columns (m=8) of microlenses 34A. Among the microlenses 34A, the microlenses located in the 1^{st} row to 8^{th} row of column a through column f are respectively designated as lenses a1 to a8, b1 to b8, c1 to c8, dl to d8, e1 to e8, and f1 to f8. In this example, among the m rows and n columns, a set of p rows and q columns (m=p=8) of microlenses 34A is selected for use in forming the convergence points in the laser irradiation step. The number of laser irradiations (number of shots) for each converged region is supposed to be 8.

FIG. 5(b) is a schematic diagram illustrating exemplary converged regions 101a of the amorphous silicon film 101. The converged regions 101a are disposed in M rows and N columns on the amorphous silicon film 101. The column direction of the converged regions 101a is the same x direction as the column direction and scanning direction concerning the microlenses 34A, whereas the row direction of the converged regions 101a is the same y direction as the row direction concerning the microlenses 34A.

FIG. 6 is a diagram showing, for each converged region 101a in an arbitrary column (designated as column k) among the N columns of converged regions 101a on the amorphous silicon film, which microlens 34A is used to perform 8 instances of laser irradiation. The vertical axis represents time, and the horizontal axis represents the position of the converged region along the scanning direction (column direction).

First, the convergence unit 30 and the irradiation region R1 are placed so that the converged regions 101a in column k and the lenses in column a of the convergence unit correspond. Next, the aforementioned laser irradiation step and stepping step are repeated 8 times. For example, at the 8^{th} instance of the laser irradiation step, lenses a8 to a1 are respectively used to perform laser irradiation for the converged regions 101a in the 1^{st} row to 8^{th} row of column k.

Through the aforementioned 8 instances of the laser irradiation step, as shown in FIG. 6, the converged region 101a in column k, 1^{st} row is subjected to 8 instances of laser irradiation by using lenses a1 to a8. The converged region 101a in column k, 2^{nd} row is irradiated with laser beams 7 times by using lenses a1 to a7. Similarly, the converged region 101a in column k, 3^{rd} row is irradiated with laser beams 6 times by using lenses a1 to a6.

In this example, after the 8^{th} instance of the laser irradiation step and before the 9^{th} instance of the laser irradiation step, a row-direction disturbance step is performed. In the row-direction disturbance step, the convergence unit 30 is caused to move with respect to the irradiation region R1 by 2 pitches along the row direction, so that the converged regions 101a in column k correspond to the lenses in column c of the convergence unit 30.

Thereafter, when a 9^{th} instance of the laser irradiation step is performed, the converged regions 101a in column k, 2^{nd} row to 9^{th} row are subjected to laser irradiation by using lenses c8 to c1, respectively.

Next, the laser irradiation step and the stepping step are repeated another 8 times. Through this, 8 instances of the laser irradiation step for the converged regions 101a in column k, 3^{rd} row to 10^{th} row are sequentially completed. For example, the converged region 101a in the 10^{th} row of column k is subjected to 8 instances of laser irradiation by using lenses c1 to c8.

Thereafter, a 2^{nd} instance of the row-direction disturbance step is performed. Through this, for example, the convergence unit 30 is caused to move with respect to the irradiation region R1 by 2 pitches in the opposite direction to the 1^{st} instance of the row-direction disturbance step, so that the converged regions in column k correspond to the lenses in column a of the convergence unit 30. After the 2^{nd} instance of the row-direction disturbance step, similarly, the laser irradiation step and the stepping step are repeated to perform laser irradiation steps for the converged regions at column k, 11^{th} row and onwards.

As can be seen from FIG. 6, with the row-direction disturbance step, the combination of eight microlenses 34A used in the laser irradiations for the converged regions 101a in the same column can be made to differ. In this example, the respective lens combinations used in the laser irradiations for the converged regions 101a in the 1^{st} row to 9^{th} row of column k are (a1-a8), (a1-a7, c8), (a1-a6, c7, c8) . . . (c1-c8), which are all different. A part of the converged regions 101a (which in this example is the converged regions 101a in the 9^{th} row and the 10^{th} row) may be subjected to laser irradiation by using the same lens combination.

Although this is not shown, when the row-direction disturbance step is not performed, all of the converged regions in the same column (e.g., column k) will be subjected to 8 instances of laser irradiation by using the same lens combination (e.g., lenses a1 to a8). Therefore, as described earlier, due to the processing accuracy for the microlens array 34, etc., column by column of c-Si islands differing in crystallinity may be formed, thus resulting in streak unevenness. On the other hand, according to the present embodiment, at least a part of the M converged regions 101a in the same column is subjected to 8 instances of laser irradiation with a different lens combination than in another part. Therefore, it is possible to restrain c-Si islands differing in crystallinity from being placed in streaks over the entire substrate, whereby streak unevenness can be reduced.

As illustrated above, the timing with which to perform the row-direction disturbance step may be randomly selected. Moreover, in the row-direction disturbance step, the number of pitches by which the convergence unit 30 is caused to make a relative movement with respect to the irradiation region R1 may also be randomly selected.

Although the number of instances of the disturbance step is not particularly limited, for example, at least one instance of the row-direction disturbance step may be performed while p instances of the laser irradiation step are performed. This makes it possible to use a different combination of p microlenses 34A to perform laser irradiation for each of p adjacent converged regions adjoining along the column direction on the amorphous silicon film, whereby streak unevenness can be suppressed more effectively.

The number of instances of the disturbance step may be even smaller. For example, while 5×p instances of the laser irradiation step are performed, at least one instance of the row-direction disturbance step may be performed. Alternatively, while M/3 instances (where M is the number of rows of converged regions) or M/5 instances of the laser irradiation step are performed, at least one instance of the row-direction disturbance step may be performed. If the number of instances of the disturbance step is reduced, a plurality of c-Si islands that have been subjected to laser irradiation by the same combination of lenses will be formed along the column direction; however, such a column will be shorter in length than in the case where no disturbance step is performed, and thus will be less likely to be visually recognized as streak unevenness.

### Second Embodiment

A laser annealing apparatus according to a second embodiment is similar to the laser annealing apparatus 100 shown in FIG. 1. However, the disturbance mechanism is configured to be capable of causing relative movements between the convergence unit 30 and the irradiation region R1 in the x direction (scanning direction) or in the −x direction. Moreover, the number m of rows of microlenses 34A in the convergence unit 30 is greater than the number p of rows in the selected lens set (m>p).

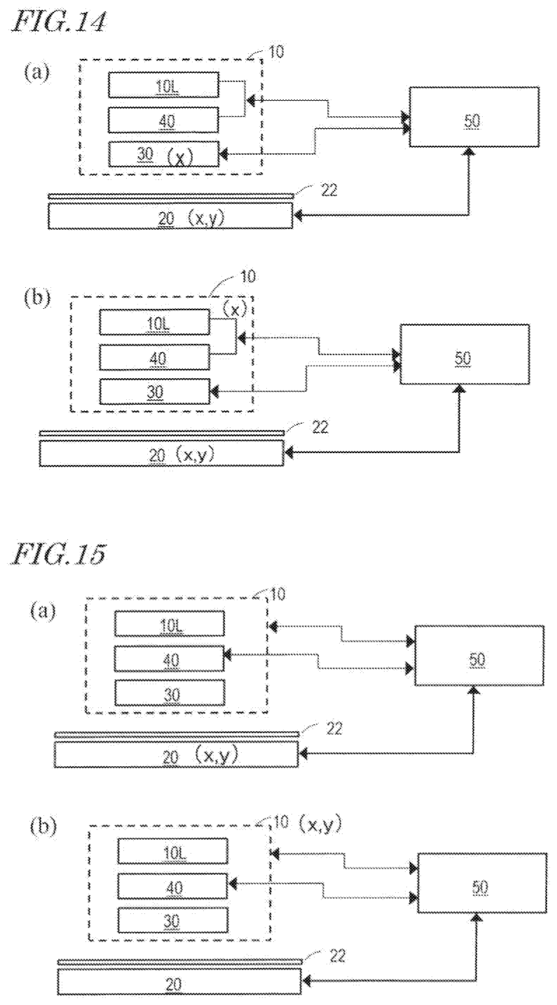

FIGS. 14(a) and (b) are schematic diagrams describing examples of operation of the control section 50 of the laser annealing apparatus according to the present embodiment.

As shown in the figure, similarly to the above-described embodiment (FIG. 13), the control section 50 controls the stage 20 (substrate 22) (or the laser irradiation device 10, rather than the stage 20) to move along the x axis and along the y axis. This realizes the scanning mechanism. Moreover, the control section 50 controls the convergence unit 30 to move with respect to the laser device 10L along the x axis, or controls the laser device 10L (or the light shield plate 40, rather than the instead laser device 10L) to move with respect to the convergence unit 30 along the x axis (FIG. 14(b)), at least once while the stage 20 (substrate 22) or the laser irradiation device 10 is being moved along the x axis (FIG. 14(a)). This realizes the disturbance mechanism.

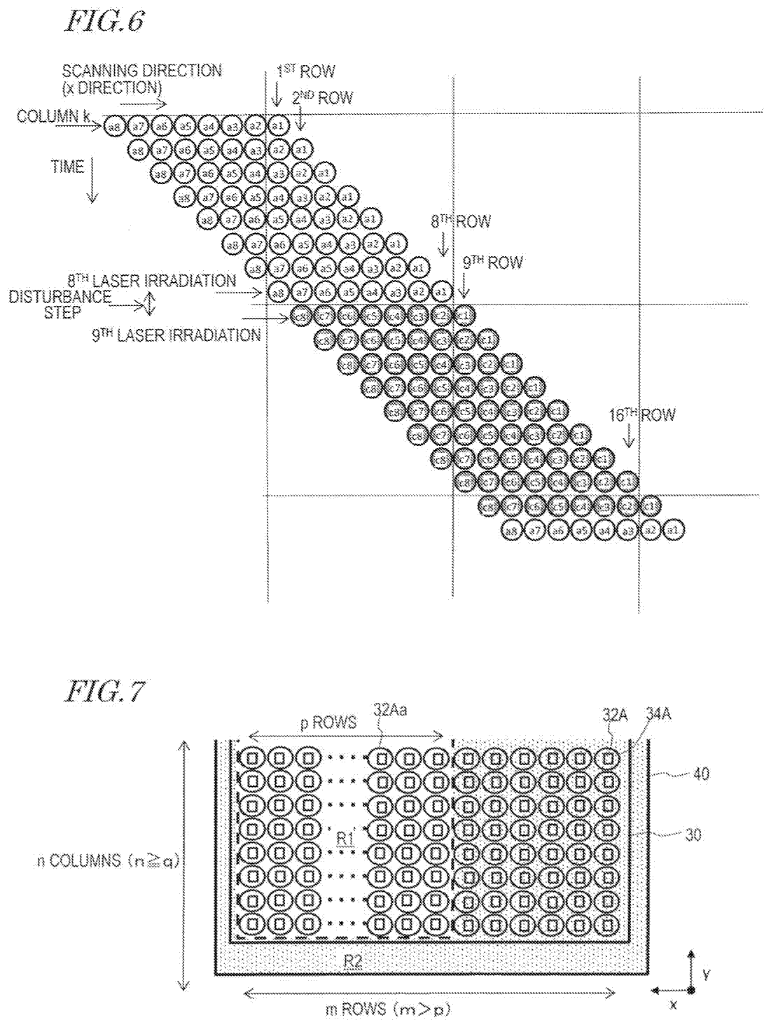

FIG. 7 is a plan view illustrating an exemplary positional relationship between the microlenses 34A of the convergence unit 30 and the irradiation region R1 according to the present embodiment.

As shown in FIG. 7, p rows and q columns (p<m, q≤n) of microlenses 34A among the m rows and n columns of microlenses 34A of the convergence unit 30 are located so as to overlap the irradiation region R1 when viewed from the normal direction of the substrate 22. The other microlenses 34A are located so as to overlap the non-irradiation region R2.

Among the m rows of microlenses 34A, the number of rows that are not included in the selected lens set (i.e., the number of excess rows) is designated as R(R=m−p). Given that m>p, n=q, the number S of lens sets consisting of p rows and q columns of microlenses 34A that are selectable from the m rows and n columns of microlenses 34A is (R+1). The number R of excess rows may be one or more. This makes it possible to select from among two or more lens sets, thus providing the effect of reducing streak unevenness through disturbance operations. In the example shown in FIG. 7, the number R of excess rows is six, and seven lens sets are selectable.

The preferable range of the number R of excess rows may be similar to the range of the number C of columns in the earlier embodiment. In other words, the number R of excess rows and the number p of shots for forming one c-Si island may preferably satisfy formula (3), and more preferably satisfy formula (4) below.

2^{R+1}≥p (3)

R≥p−1 (4)

On the other hand, the number R of excess rows may be less than 2×p, for example. This is advantageous because the aforementioned effects can be obtained without considerably increasing the number of microlenses (e.g., the number of microlenses: less than p×q×2).

<Laser Annealing Method>

Next, a method of performing laser annealing of an amorphous silicon film will be described. Herein, a plurality of laser beams are sequentially converged onto a plurality of converged regions arranged in M rows and N columns on the amorphous silicon film, thereby forming a plurality of c-Si islands. Hereinafter, mainly differences from the laser annealing method according to the first embodiment will be described, while description concerning similar steps (including material, conditions of formation, etc.) may be conveniently omitted.

First, the substrate 22 having an amorphous silicon film on its surface is placed on the bed plane of the stage of the laser annealing apparatus 100. Next, among the plurality of microlenses 34A arranged in m rows and n columns, p rows and q columns of microlenses (p<m and q≥n) 34A are used to form p rows and q columns of laser beams LB, and to form respective convergence points of the p rows and q columns of laser beams LB in a plurality of converged regions located in the irradiation region R1 (laser irradiation step).

Then, a stepping step of causing the substrate 22 to make a relative movement with respect to the irradiation region R1 by one pitch along the scanning direction (the x direction) is performed. Thereafter, a next laser irradiation step and stepping step are performed. Thus, by repeating laser irradiation steps and stepping steps, among the M rows and N columns, a respectively corresponding convergence point is formed p times in each of the plurality of converged regions arranged in M rows and q columns (q<N). As a result, c-Si islands are formed respectively in the plurality of converged regions.

In the present embodiment, before having formed convergence points of p instances of laser beams in all regions of the M rows and the q columns, the disturbance mechanism is employed to perform, at least once, a step of causing the convergence unit 30 to make a relative movement with respect to the irradiation region R1 by at least one pitch along the x axis (in the x direction or in the −x direction). This step is referred to as a “column-direction disturbance step”. This allows at least a part of the selected lens set to be used in the laser irradiation step to differ. The timing with which to perform the column-direction disturbance step, the number of times of performing it, the number of pitches by which movements are to be made, etc., may be selected as appropriate. These may be randomly selected, too.

In a similar manner, among the M rows and N columns, any other converged region of M rows and q columns is also subjected to p instances of laser irradiation each. In this manner, c-Si islands are respectively formed in the M rows and N columns of converged regions. The subsequent steps are similar to those in the first embodiment.

Next, an example of the aforementioned laser annealing method will be described.

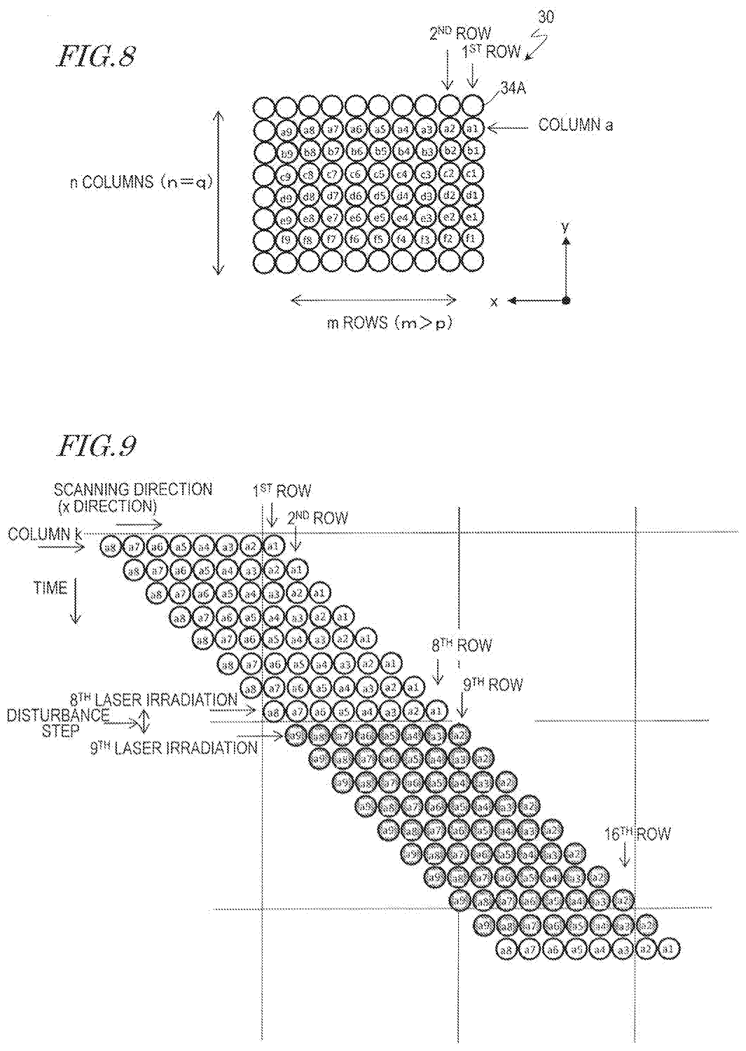

FIG. 8 is a schematic plan view illustrating an exemplary convergence unit 30 used in the laser annealing method. The convergence unit 30 includes m rows and n columns of microlenses 34A. In FIG. 8, as in FIG. 5(a), a part of the microlenses 34A are denoted with reference numerals. In this example, the number m of rows of microlenses 34A is greater than the number p of rows in the select lens set, and the number n of columns of microlenses 34A is equal to the number q of columns in the selected lens set (m>p and n=q). Moreover, as shown in FIG. 5(b), each converged region of the amorphous silicon film is subjected to 8 instances of laser irradiation (i.e., p=8), thereby forming c-Si islands.

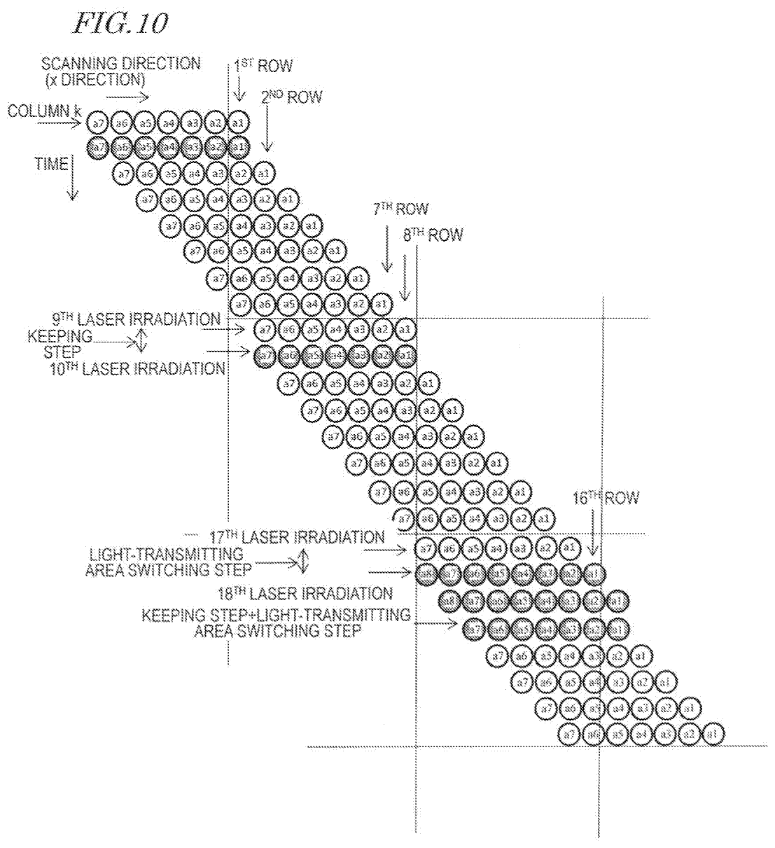

FIG. 9 is a diagram showing, for each converged region in an arbitrary column (designated as column k) among the N columns of converged regions on the amorphous silicon film, which microlens 34A is used to perform 8 instances of laser irradiation. The vertical axis represents time, and the horizontal axis represents the position of the converged region along the scanning direction (column direction).

First, the convergence unit 30 and the irradiation region R1 are placed so that the converged regions in column k and the lenses in column a of the convergence unit 30 correspond. Next, the aforementioned laser irradiation step and stepping step are repeated 8 times. As a result, as shown in FIG. 9, the converged region in column k, 1^{st} row is subjected to 8 instances of laser irradiation by using lenses a1 to a8. Note that the converged region in column k, 2^{nd} row is irradiated with laser beams 7 times by using lenses a1 to a7. Similarly, the converged region in column k, 3^{rd} row is irradiated with laser beams 6 times by using lenses a1 to a6.

In this example, after the 8^{th} instance of the laser irradiation step and before the 9^{th} instance of the laser irradiation step, a column-direction disturbance step is performed. In the column-direction disturbance step, the convergence unit 30 is caused to move with respect to the irradiation region R1 by 1 pitch along the column direction, so that the converged regions in the 2^{nd} row to 9^{th} row of column k correspond to lenses a2 to a9 of the convergence unit 30. In this state, the 9^{th} instance of the laser irradiation step is performed.

Next, the laser irradiation step and the stepping step are repeated another 8 times. Through this, 8 instances of the laser irradiation step up to the converged region in column k, 10^{th} row are sequentially completed. For example, the converged region in the 10^{th} row of column k is subjected to 8 instances of laser irradiation by using lenses a2 to a9.

Thereafter, a 2^{nd} instance of the column-direction disturbance step is performed. Through this, for example, the convergence unit 30 is caused to move with respect to the irradiation region R1 by 1 pitch in the opposite direction to the 1^{st} instance of the column-direction disturbance step. Thereafter, similarly, the laser irradiation step and the stepping step are repeated to perform laser irradiation steps for the converged regions at column k, 11^{th} row and onwards.

As can be seen from FIG. 9, by performing the column-direction disturbance step, the combination of eight microlenses 34A used in the laser irradiations for the converged regions in the same column can be made to differ. In this example, the respective lens combinations used in the laser irradiations for the converged regions in the 1^{st} row to 9^{th} row of column k are (a1-a8), (a1-a7, a9), (a1-a6, a8, a9) . . . (a2-a9), which are all different. A part of the converged regions (which in this example is the converged regions in the 9^{th} row and the 10^{th} row) may be subjected to laser irradiation by using the same lens combination.

Thus, in the present embodiment, a part of the M converged regions in the same column can be subjected to 8 instances of laser irradiation by using a different combination of microlenses 34A than those for another part of the converged regions. Therefore, it is possible to restrain c-Si islands differing in crystallinity from being placed in streaks over the entire substrate, whereby streak unevenness can be reduced.

As illustrated above, the timing with which to perform the column-direction disturbance step may be randomly selected. Moreover, in the column-direction disturbance step, the direction (the x direction, the −x direction) and the number of pitches by which the convergence unit 30 is caused to make a relative movement with respect to the irradiation region R1 may also be randomly selected.

Although the number of instances of the column-direction disturbance step is not particularly limited, it may be similar to the number of instances of the aforementioned row-direction disturbance step. For example, while 5×p instances of the laser irradiation step are performed, and preferably while p instances of the laser irradiation step are performed, at least one instance of the column-direction disturbance step may be performed. This makes it possible to use a different combination of p microlenses 34A to perform laser irradiation for each of p adjacent converged regions adjoining along the column direction on the amorphous silicon film, whereby streak unevenness can be suppressed more effectively.

Alternatively, while M/3 instances (where M is the number of rows of converged regions) or M/5 instances of the laser irradiation step are performed, at least one instance of the column-direction disturbance step may be performed.

<Variant>

The disturbance mechanism of the laser annealing apparatus according to the present embodiment may be configured to be capable of causing the convergence unit 30 to make relative movements with respect to the irradiation region R1 both along the column direction and along the row direction. This will make it possible, before having formed convergence points of p instances of laser beam in all regions of the M rows and the q columns in the aforementioned laser annealing method, to perform at least one of or both of the column-direction disturbance step and the row-direction disturbance step, for example. In the case where both of the column-direction disturbance step and the row-direction disturbance step are to be performed, the number m of rows of microlenses 34A in the convergence unit 30 may be greater than the number p of rows in the selected lens set, and the number n of columns of microlenses 34A may be greater than the number q of columns in the selected lens set. That is, a convergence unit 30 having n rows and m columns (n>p, m>q) of microlenses 34A may be adopted.

The timing, disturbance direction, number of pitches with which to perform the row-direction disturbance step and the column-direction disturbance step may respectively be randomly selected. Both of the column-direction disturbance step and the row-direction disturbance step may be allowed to be performed after one laser irradiation step and before a next laser irradiation step (i.e., between shots).

the total number of instances of column-direction disturbance steps and row-direction disturbance steps is not particularly limited. For example, while 5×p instances, or p instances of the laser irradiation step are performed, at least one instance of the column-direction (or row-direction) disturbance step may be performed. Alternatively, while M/3 instances (where M is the number of rows of converged regions) or M/5 instances of the laser irradiation step are performed, at least one instance of the column-direction (or row-direction) disturbance step may be performed.

### Third Embodiment

A laser annealing apparatus according to a third embodiment includes a disturbance mechanism to control relative positions between the irradiation region R1 and the substrate. A difference from the laser annealing apparatuses 100 and 200 used in the earlier embodiments is that the convergence unit 30 does not need to make relative movements with respect to the irradiation region R1 (i.e., the selected lens set does not need to be shifted). Moreover, the microlens array of the convergence unit does not need to include excess lens columns or excess lens rows.

Moreover, the laser annealing apparatus according to the present embodiment may include a light-transmitting area alteration mechanism that is capable of switching the area of the irradiation region. The light-transmitting area alteration mechanism is able to switch the area of the irradiation region between: an area corresponding to p rows and q columns of microlenses; and an area corresponding to t rows and q columns (t<p) of microlenses, for example. Use of the light-transmitting area alteration mechanism allows the selected lens set to be switched between a lens set of p rows and q columns (first lens set) and a lens set of t rows and q columns (second lens set). The light-transmitting area alteration mechanism may include a shutter which is capable of opening/closing that is disposed between the substrate and the laser device, for example. The shutter may be attached to a light shield plate.

Note that the selected lens set may be selected from among a plurality of lens sets including the first lens set and the second lens set.

FIGS. 15(a) and (b) are schematic diagrams describing examples of operation of the control section 50 in the laser annealing apparatus according to the present embodiment.

As shown in the figures, the control section 50 controls the stage 20 (substrate 22) or the laser irradiation device 10 to move along the x axis and along the y axis. This realizes the scanning mechanism. Moreover, the control section 50 controls the stage 20 (substrate 22) or the laser irradiation device 10 so as not to move along the x axis between shots (i.e., not performing a stepping) at least once while the stage 20 (substrate 22) or the laser irradiation device 10 is being moved along the x axis. This realizes the disturbance mechanism. Furthermore, in addition to the above operation, the control section 50 may perform control to alter the area of the light-transmitting portion of the light shield plate 40, at least once while the stage 20 (substrate 22) or the laser irradiation device 10 is being moved along the x axis. This realizes the light-transmitting area alteration mechanism.

Hereinafter, a laser annealing method according to the third embodiment will be described.

In the present embodiment, too, by using the laser annealing apparatus, a plurality of laser beams are sequentially converged onto a plurality of regions (converged regions) of the amorphous silicon film, thereby forming a plurality of c-Si islands arranged in M rows and N columns.

First, a substrate having an amorphous silicon film on its surface is placed on the bed plane of the laser annealing apparatus. Thereafter, a laser irradiation step is performed. In the laser irradiation step, respective convergence points of laser beams to be created by microlenses of the selected lens set are formed in a plurality of converged regions of the amorphous silicon film. For example, when a set of t rows and q columns of microlenses (second lens set) is selected, respective convergence points of the t rows and q columns of laser beams that are created by the t rows and q columns of microlenses are formed.

If the second lens set is selected, the t rows and q columns of microlenses are placed at positions corresponding to the irradiation region, and the laser irradiation step is performed in this state.

After the laser irradiation step, either a stepping step of causing the substrate to make a relative movement with respect to the irradiation region by one pitch along the column direction or a keeping step that keeps unchanged the relative positional relationship between the substrate and the irradiation region (disturbance step) is performed. Thereafter, a next laser irradiation step is performed. Thus, by repeating the laser irradiation step and the stepping step or keeping step, among the M rows and N columns, a respectively corresponding convergence point is formed p times in each of the plurality of converged regions arranged in M rows and q columns (q<N). As a result, c-Si islands are formed respectively in the plurality of converged regions.

In the present embodiment, before having formed convergence points of the plurality of laser beams in all regions of the M rows and the q columns, at least one instance of the keeping step is performed. For example, while 5×p instances of the laser irradiation step are performed, at least one instance of the keeping step may be performed. If the keeping step is performed, each converged region which was irradiated with a laser beam in a previous laser irradiation step is again irradiated, in a next laser irradiation step, with a laser beam by using the same lens. In the case where e.g. p−t=1, in order to perform p instances of laser irradiation for each converged region by only using t rows and q columns of microlenses, one instance of keeping step may be performed in the course of p instances of the laser irradiation step.

Before having formed convergence points of the plurality of laser beams in all regions of the M rows and the q columns, at least one instance of a light-transmitting area switching step may be performed, which alters the selected lens set and switches the area of the irradiation region in accordance with this altered lens set. In the light-transmitting area switching step, for example, the area of the irradiation region may be altered through opening/closing of a shutter.

An example of the light-transmitting area switching step will be described. For example, after performing a laser irradiation step by using t rows and q columns of microlenses, p rows and q columns of microlenses may be selected, and the area of the irradiation region may be increased so as to correspond to the selected p rows and q columns of microlenses. The selected p rows and q columns of microlenses are positioned so as to correspond to the altered irradiation region, and a next laser irradiation step is performed. Similarly, after performing a laser irradiation step by using p rows and q columns of microlenses, in order to select t rows and q columns of microlenses, the area of the irradiation region may be decreased so as to correspond to the selected t rows and q columns of microlenses.

In the present embodiment, by performing the aforementioned keeping step, the combination of p lenses to be used in the laser irradiations for a plurality of converged regions in the same column can be made to differ. Hereinafter, a specific example thereof will be described.

In this example, a convergence unit similar to the convergence unit 30 illustrated in FIG. 5(a) is used. It is assumed that the number m of rows and the number n of columns of microlenses 34A are equal to the number p of rows and the number q of columns in the first lens set (m=p=8, n=q). Moreover, as shown in FIG. 5(b), the converged regions disposed in M rows and N columns on the amorphous silicon film are subjected to 8 instances of laser irradiation (i.e., p=8), thereby forming c-Si islands.

FIG. 10 is a diagram showing, for each converged region in an arbitrary column (designated as column k) among the N columns of converged regions on the amorphous silicon film, which microlens 34A is used to perform 8 instances of laser irradiation. The vertical axis represents time, and the horizontal axis represents the position of the converged region along the scanning direction (column direction).

First, the convergence unit 30 and the irradiation region are placed so that converged regions in column k and the lenses in column a of the convergence unit 30 correspond. The irradiation region is chosen so as to correspond to the second lens set (t rows and q columns; herein t=7).

Next, after a 1^{st} instance of laser irradiation is performed, the keeping step is performed. Thereafter, the laser irradiation step and the stepping step are repeated 8 times. Thus, as shown in FIG. 10, the converged region in the column k, 1^{st} row is subjected to a total of 8 instances of laser irradiation by using lenses a1, a1, and a2 to a7.

After a 9^{th} instance of the laser irradiation step, a 2^{nd} instance of the keeping step is performed, and then a 10^{th} instance of the laser irradiation step is performed. In the 10^{th} instance of the laser irradiation step, similarly to the 9^{th} instance of the laser irradiation step, the converged regions in the 2^{nd} row to 8^{th} row of column k are subjected to laser irradiation by using lenses a7 to a1. Through this, a total of 8 instances of laser irradiation for the converged region in column k, 2^{nd} row are completed, by using lenses a1 to a6, a7, and a7.

Thereafter, for example, between a 17^{th} instance of the laser irradiation step and a 18^{th} instance of the laser irradiation step, a light-transmitting area switching step may be performed, in order to switch the irradiation region so as to correspond to the first lens set (p rows and q columns). In the 18^{th} instance of the laser irradiation step, eight converged regions in the 9^{th} row to 16^{th} row of column k are subjected to laser irradiation by using lenses a8 to a1. Through this, a total of 8 instances of laser irradiation for the converged region in column k, 9^{th} row is completed, by using lenses a1 to a8.

Thus, by performing a keeping step instead of a stepping step with appropriate timing, the combination of eight microlenses 34A used in the laser irradiations for the converged regions in the same column can be made to differ. In this example, the respective lens combinations used in the laser irradiations for the converged regions in the 1^{st} row to 7^{th} row of column k are (a1, a1-a7), (a1-a7, a7), (a1-a6, a6, a7) . . . (a1, a2, a2-a7), which are all different. Thus, according to the present embodiment, at least a part of the M converged regions in the same column can be subjected to 8 instances of laser irradiation by using a different lens combination than in another part.

When the keeping step alone is performed, for example, laser irradiations for the converged regions in the 8^{th} row to 14^{th} row might be performed by using the same combinations of lenses as for the converged regions in the 1^{st} row to 7^{th} row of column k, respectively. Therefore, some regularity may occur in the distribution of crystallinity. On the other hand, by performing the light-transmitting area switching step, the lens combination can be changed with an arbitrary timing, whereby regularity can be further broken.

Thus, also in the present embodiment, it is possible to restrain c-Si islands differing in crystallinity from being placed in streaks over the entire substrate, whereby streak unevenness can be reduced. The present embodiment is advantageous because streak unevenness can be reduced while suppressing an increase in the number of microlenses 34A in the convergence unit 30.

The timings with which to perform the keeping step and the light-transmitting area switching step may be randomly selected. For example, while the second lens set is being selected, (p−t) instances of the keeping step may be performed for every p instances of laser irradiation. Moreover, while e.g. 5×p instances of the laser irradiation step are performed, at least one instance of the light-transmitting area switching step may be performed. Alternatively, while M/3 instances (where M is the number of rows of converged regions) or M/5 instances of the laser irradiation step are performed, at least one instance of the light-transmitting area switching step may be performed.

<Variant>

In the present embodiment, too, the aforementioned row-direction disturbance step and/or column-direction disturbance step may be performed. In this case, the number of microlenses 34A (m rows and n columns) may be made greater than p rows and q columns (m>p and/or n>q)). For example, between laser irradiations (i.e., between shots), the keeping step and the column-direction (or row-direction) disturbance step may be performed, or the stepping step and the column-direction (or row-direction) disturbance step may be performed. Thus, by combining the keeping step and the column-direction (or row-direction) disturbance step, streak unevenness can be reduced more effectively than in the case of performing the keeping step alone. Moreover, the number of microlenses 34A in the convergence unit 30 can be reduced as compared to the case where column-direction (or row-direction) disturbance step alone is performed. In the case where the keeping step and the column-direction (or row-direction) disturbance step are combined, the light-transmitting area switching step does not need to be performed.

(Variants of Laser Annealing Apparatus)

Hereinafter, variants of the laser annealing apparatus used in the first to third embodiments will be described.

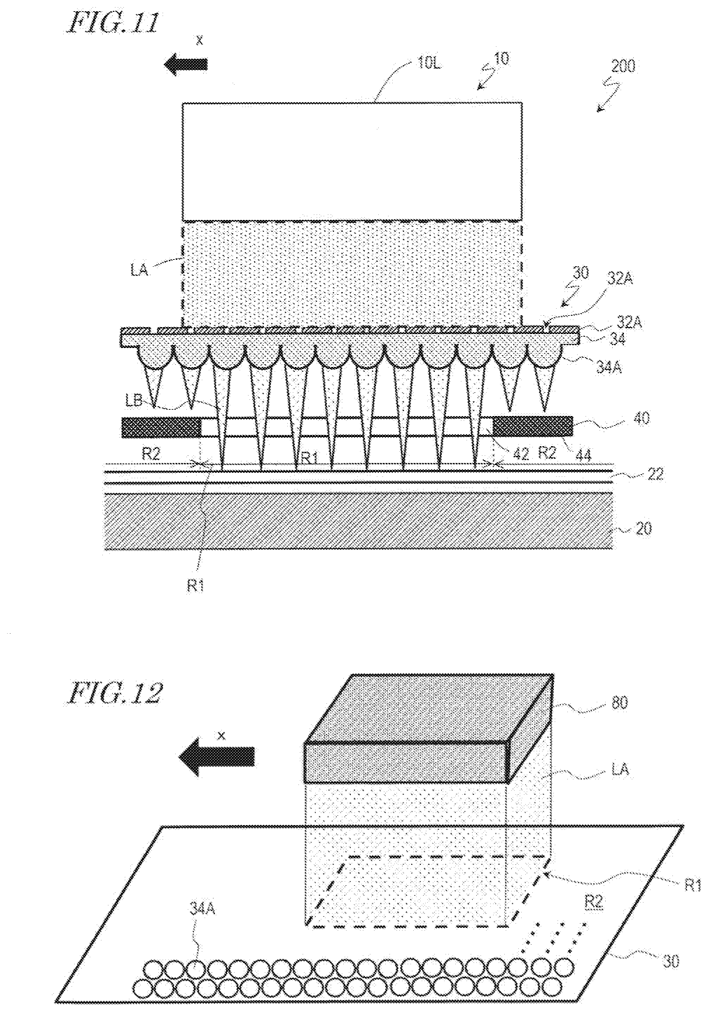

FIG. 11 is a cross-sectional view showing Variant 1 of the laser annealing apparatus.

The laser annealing apparatus 200 of Variant 1 differs from the laser annealing apparatus 100 shown in FIG. 2 in that the light shield plate 40 is disposed between the convergence unit 30 and the substrate 22.

The light shield plate 40 includes a light-transmitting portion 42, which defines the irradiation region R1, and a light-shielding portion 44 located around the light-transmitting portion 42. The convergence unit 30 is disposed so that, when viewed from the normal direction of the substrate 22, p rows and q columns of microlenses 34A among the microlenses 34A of the convergence unit 30 overlap the irradiation region R1, and the other microlenses 34A overlap the non-irradiation region R2.

When partial laser annealing is performed by using the laser annealing apparatus 200 of Variant 1, a plurality of laser beams LB emitted toward the substrate 22 from the laser device 10L and through the p rows and q columns of microlenses 34A pass through the light-transmitting portion 42 of the light shield plate 40 so as to reach the substrate 22. On the other hand, laser beams LB emitted toward the substrate 22 through the other microlenses 34A are blocked by the light-shielding portion 44 of the light shield plate 40, and do not reach the substrate 22. Otherwise, it is similar in constitution to the laser annealing apparatus 100.

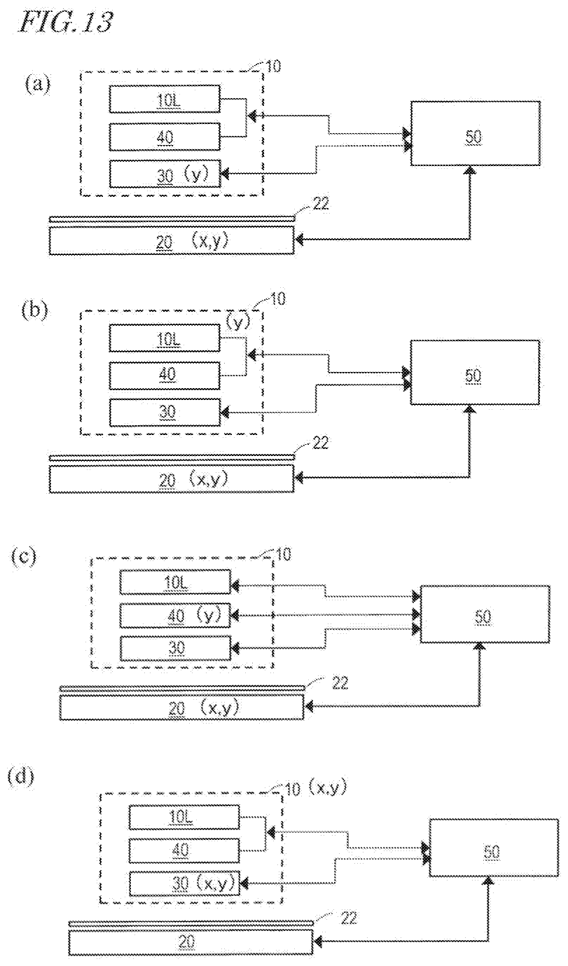

FIG. 12 is a perspective view showing a portion of Variant 2 of the laser annealing apparatus.

The laser annealing apparatus of Variant 2 differs from the laser annealing apparatus 100 shown in FIG. 2 in that, instead of the light shield plate 40 (FIG. 2, FIG. 11), a cylindrical lens 80 is included as an optical element defining the scanning region. The cylindrical lens 80 is disposed between the convergence unit 30 and the laser device 10L. Otherwise, it is similar in constitution to the laser annealing apparatus 100 (FIG. 2).

### INDUSTRIAL APPLICABILITY

Laser annealing methods and laser annealing apparatuses according to embodiments of the present invention are suitably used for producing a semiconductor device that includes thin film transistors. In particular, they are suitably used for the production of large-area liquid crystal display apparatuses and organic EL display apparatuses.

### REFERENCE SIGNS LIST

10: laser irradiation device
10L: laser device
20: stage
22: substrate
30: convergence unit
32: mask
32A: aperture
34: microlens array
34A: microlens
40: light shield plate
42: light-transmitting portion
44: light-shielding portion
50: control section
80: cylindrical lens
101: amorphous silicon film
101a: converged region
LA: laser beam
LB: laser beam
R1: irradiation region
R2: non-irradiation region
100, 200: laser annealing apparatus

1. A laser annealing apparatus comprising:
a stage having a bed plane for receiving a substrate; and
a laser irradiation device to emit a plurality of laser beams toward the bed plane to form an irradiation region on the bed plane,
the laser irradiation device including:
a laser device to emit a laser beam; and
a convergence unit that includes a microlens array having a plurality of microlenses arranged in m rows and n columns and a mask having a plurality of apertures disposed respectively for the plurality of microlenses, wherein the convergence unit receives the laser beam emitted from the laser device to form respective convergence points of the plurality of laser beams within the irradiation region, wherein,
the plurality of laser beams are p rows and q columns of laser beams formed by p rows and q columns of microlenses (p<m or q<n) among the plurality of microlenses arranged in the m rows and the n columns; and
the laser irradiation device further includes a disturbance mechanism to alter a relative positioning between the convergence unit and the irradiation region so that, from among the plurality of microlenses arranged in the m rows and the n columns, at least two different sets of p rows and q columns of microlenses are selectable.

2. The laser annealing apparatus of claim 1, wherein,
the laser beam is large enough to irradiate more microlenses than p rows and q columns of microlenses among the plurality of microlenses arranged in the m rows and the n columns;
the laser irradiation device further includes a light shield plate having a light-transmitting portion that stipulates the irradiation region; and
the light-transmitting portion has an area corresponding to p rows and q columns of microlenses (p<m or q<n) among the plurality of microlenses arranged in the m rows and the n columns.

3. The laser annealing apparatus of claim 2, wherein the light shield plate is disposed between the laser device and the convergence unit.

4. The laser annealing apparatus of claim 2, wherein the light shield plate is disposed between the convergence unit and the substrate.

5. The laser annealing apparatus of claim 1, wherein the disturbance mechanism causes a position of the convergence unit with respect to the irradiation region to move along a disturbance direction which is orthogonal to a scanning direction of the laser irradiation device.

6. The laser annealing apparatus of claim 1, wherein the disturbance mechanism causes a position of the convergence unit with respect to the irradiation region to move along a scanning direction of the laser irradiation device.

7. A laser annealing method of sequentially converging a plurality of laser beams in a plurality of regions of an amorphous silicon film to form a plurality of crystalline silicon islands arranged in M rows and N columns, the method comprising:
step A: a step of providing: a stage having a bed plane for receiving a substrate; and a laser irradiation device to emit a plurality of laser beams toward the bed plane to form an irradiation region on the bed plane, the laser irradiation device including a laser device to emit a laser beam and a convergence unit that includes a microlens array having a plurality of microlenses arranged in m rows and n columns and a mask having a plurality of apertures disposed respectively for the plurality of microlenses;
step B1: a step of placing on the bed plane a substrate having an amorphous silicon film on a surface thereof;
step C1: a step of employing the laser irradiation device to form, as the plurality of laser beams, p rows and q columns or t rows and q columns of laser beams by using p rows and q columns (p≤m and q≤n) or t rows and q columns (t<p) of microlenses among the plurality of microlenses arranged in the m rows and the n columns, and to form respective convergence points of the plurality of laser beams in the plurality of regions of the amorphous silicon film; and
step C2: a step of, after step C1, causing the substrate to make a relative movement with respect to the irradiation region by one pitch along a column direction, wherein,
the method comprises step D including a sequence of performing step C1 followed by step C2, and thereafter step C1, wherein step D forms a respectively corresponding convergence point p times in each of the plurality of regions to become the plurality of crystalline silicon islands arranged in M rows and N columns, and the method performs, before having formed convergence points of the plurality of laser beams in all regions of the M rows and the q columns,
at least one instance of step C3: a step of, after step C1, causing a set of p microlenses to be used in forming p instances of convergence points in one of M regions belonging in one column of the plurality of regions to differ, by at least one microlens, from a set of p microlenses having been used in forming p instances of convergence points in another of the M regions.

8. The laser annealing method of claim 7, wherein,
step C1 is a step of forming, as the plurality of laser beams, p rows and q columns of laser beams by using p rows and q columns of microlenses (p≤m and q<n) among the plurality of microlenses arranged in the m rows and the n columns, and forming respective convergence points of the p rows and q columns of laser beams in the plurality of regions of the amorphous silicon film; and
step C3 comprises, after step C1, a step of causing the convergence unit to make a relative movement with respect to the irradiation region by at least one pitch along a row direction.

9. The laser annealing method of claim 7, wherein,
step C1 is a step of forming, as the plurality of laser beams, p rows and q columns of laser beams by using p rows and q columns of microlenses (p<m and q≤n) among the plurality of microlenses arranged in the m rows and the n columns, and forming respective convergence points of the p rows and q columns of laser beams in the plurality of regions of the amorphous silicon film; and
step C3 comprises, after step C1, a step of causing the convergence unit to make a relative movement with respect to the irradiation region by at least one pitch along the column direction.

10. The laser annealing method of claim 7, further comprising, before step C1,
step B2: a step of selecting, as a selected lens set, t rows and q columns of microlenses among the plurality of microlenses arranged in the m rows and the n columns, and positioning the selected lens set so as to correspond to the irradiation region, wherein,
step C1 is a step of forming the plurality of laser beams by using the selected lens set, and forming respective convergence points of the plurality of laser beams in the plurality of regions of the amorphous silicon film;
step C3 is a step of, after step C1, keeping unchanged a relative positional relationship between the substrate and the irradiation region; and
step D includes a sequence of performing step C2 or step C3, and thereafter step C1.

11. The laser annealing method of claim 10, further comprising step C4: a step of, after step C1, switching the selected lens set to p rows and q columns of microlenses (t<p≤m and q≤n) among the plurality of microlenses arranged in the m rows and the n columns, and accordingly, altering an area of the irradiation region so as to correspond to the switched selected lens set and positioning the switched selected lens set so as to correspond to the altered irradiation region, wherein,
before having formed convergence points of the plurality of laser beams in all regions of the M rows and the q columns, one or more instances of step C4 are performed.

12. The laser annealing method of claim 7, wherein at least one instance of step C3 is performed while 5×p instances of step C1 are performed.

13. The laser annealing method of claim 7, wherein at least one instance of step C3 is performed while p instances of step C1 are performed.

14. The laser annealing method of claim 7, wherein the at least one instance is randomly selected.

15. A method of producing an active matrix substrate, comprising:
a step of forming a plurality of crystalline silicon islands by the laser annealing method of claim 7; and
a step of forming a plurality of TFTs by using the plurality of crystalline silicon islands.
